(19) United States
(12) Patent Application Publication
(10) Pub. No.: US 2013/0037101 A1
(43) Pub. Date: Feb. 14, 2013

(54) PHOTOVOLTAIC CELL COMPRISING A REGION SUSPENDED BY A CONDUCTIVE PATTERN AND PRODUCTION PROCESS

(71) Applicants: Raphael Cabal, Perigueux (FR); Bernadette Grange, Chambery (FR)

(72) Inventors: Raphael Cabal, Perigueux (FR); Bernadette Grange, Chambery (FR)

(73) Assignee: COMMISSARIAT A L'ENERGIE ATOMIQUE ET AUX ENERGIES ALTERNATIVES, Paris (FR)

(21) Appl. No.: 13/641,721

(22) PCT Filed: Apr. 29, 2011
(86) PCT No.: PCT/FR11/00264

§ 371 Date: Oct. 17, 2012

(30) Foreign Application Priority Data
May 6, 2010 (FR) 10/01948

(51) Int. Cl. H01L 31/0224; H01L 31/18; H01L 31/0216

(52) U.S. Cl. 136/256; 438/57; 257/E31.119

(57) ABSTRACT

The photovoltaic cell includes an electrically conductive passivation film separated from an electrically conductive collection layer and a substrate. An electrically conductive connection pattern maintains an area of the collection layer in suspension with respect to the passivation film. Suspension of the collection layer is obtained by making an etching agent pass through a permeable area of the collection layer.

### BACKGROUND OF THE INVENTION

The invention relates to a photovoltaic cell comprising:
a substrate,
an electrically conductive collection layer,
an electrically conductive passivation film separating the collection layer from the substrate,

The invention also relates to a method for producing a photovoltaic cell.

### STATE OF THE ART

The photovoltaic cell is formed by a multitude of layers with very specific properties in which the object of each layer used is to perform an extremely precise electric or mechanical function. These layers provide for example an operating gain on reflection of the incident radiation or on the mechanical strength over time or then again on the series resistance. However, each layer and/or each technological step is not neutral and generates mechanical stresses or technological constraints on the already integrated elements or on the elements to come.

In conventional manner, a photovoltaic cell comprises a substrate provided with a photovoltaic junction. Thus, the light radiation strikes the photovoltaic cell and is converted into an electric current which is collected by electric contacts. The contacts are arranged on the main surfaces, on each side of the substrate, to enable output of the current generated by the photovoltaic cell.

In order to increase the performances of photovoltaic cells and the viability of the solar industry, the trend is towards thinning of the cell and the use of increasingly large collection surfaces. Under these conditions, as the cell is progressively fabricated, transformations are made on the photovoltaic cells and the mechanical stresses generated are such that the cell is no longer flat.

This flatness defect is a drawback of prime importance as it greatly limits the possibilities of integration of the cells in panels which are for the most part flat and makes production automation more difficult.

The article by Huster (“Aluminium-Back Surface Field: Bow Investigation and Elimination”, 20th European Photovoltaic Solar Energy Conference and Exhibition, Barcelona 6-10 Jun. 2005) describes a cell with a back surface which is covered by a layer of silicon and aluminium alloy. This silicon and aluminium layer introduces a deformation of the photovoltaic cell. In order to eliminate or reduce this deformation of the cell, the author performs hardening of the cell in the (−20° C.; −50° C.) range, after an annealing step.

This academic approach does not appear feasible from an industrial point of view and an alternative to this method therefore has to be found in order to obtain photovoltaic cells with a flatness that is compatible with use in large series.

### OBJECT OF THE INVENTION

The object of the invention consists in producing a photovoltaic cell that is flat or substantially flat.

This problem tends to be solved by means of a cell according to the appended claims and in particular by the fact that an electrically conductive connection pattern maintains an area of the collection layer in suspension with respect to the passivation film.

It is a further object of the invention to provide a method that is easy to implement and that ensures production of flat photovoltaic cells.

This problem tends to be solved by means of a method according to the appended claims and in particular by the fact that the method comprises the following steps:
providing a substrate provided with a photovoltaic junction and covered on a main surface by an electrically conductive passivation film, an area made from sacrificial material and an electrically conductive collection layer,
degrading the sacrificial area so as to to form a suspended area in the collection layer and a connection pattern.

### BRIEF DESCRIPTION OF THE DRAWINGS

Other advantages and features will become more clearly apparent from the following description of particular embodiments of the invention given for non-restrictive example purposes only and represented in the appended drawings, in which:

FIGS. 1 and 2 represent different embodiments of a photovoltaic cell, in schematic manner in cross-section,

FIGS. 3 to 5 represent different steps of a method for producing a photovoltaic cell, in schematic manner in cross-section,

FIGS. 6 and 7 represent other steps relative to a variant of the methods for producing a photovoltaic cell, in schematic manner in cross-section.

### DESCRIPTION OF A PREFERRED EMBODIMENT OF THE INVENTION

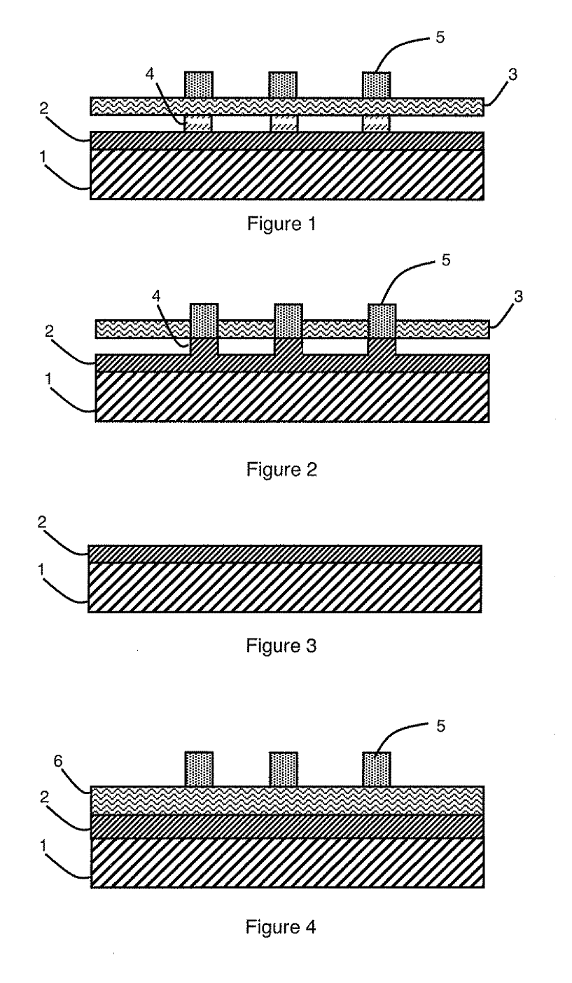

As illustrated in FIGS. 1 and 2, the photovoltaic cell comprises a substrate 1 provided with a photovoltaic junction. Substrate 1 for its part comprises opposite first and second main surfaces. The first main surface is on one side of the photovoltaic junction whereas the second main surface is on the other side of the junction.

A part of the light energy that strikes the photovoltaic cell from one of the main surfaces, the front surface, is transformed into electric charge carriers by means of the photovoltaic junction. Substrate 1 is for example a substrate 1 made from crystalline semiconductor material, in more precise manner a substrate 1 made from single-crystal or polycrystalline silicon.

The photovoltaic junction is made in substrate 1 by means of any suitable technique. For example, for a p-type substrate 1 made from silicon or from a silicon or germanium base, doping of opposite type (here of n-type) is performed on one of the main surfaces. Thus, in substrate 1, there is a p-type doped part and an n-type doped part which enables the required photovoltaic junction to be formed. The profiles of the different dopants can vary spatially so as to enhance the photovoltaic effect or the contact resistance of substrate 1 according to the locations.

The main surface of the substrate which acts as front surface for the photovoltaic cell is provided with conductive contacts (not shown) which enable output of the electric current produced in the cell. The contacts are preferably made from materials presenting a low resistivity in order to limit the access resistances, thereby not impairing operation of the cell. For example purposes, the contacts are made from metallic material, more precisely a silver-based material.

The other main surface which acts as back surface is also provided with conductive contacts which enable output of the electric current produced in the cell. The conductive contacts arranged on the opposite main surfaces represent the two output terminals of the photovoltaic cell. For example purposes, the contacts of the back surface are made from metallic material, more precisely a silver- and/or aluminium-based material. The conductive contacts are electrically connected to substrate 1 by means of different electrically conductive layers.

The conductive contacts are produced by means of any suitable technique, for example by screen printing. It is also possible to use deposition followed by an etching for localizing of the conductor. When the contacts are formed by screen printing, substrate 1 is then subjected to thermal treatment in order to eliminate the solvent associated with the contacts. In preferential manner, the contacts are formed by screen printing as this enables a reduction of costs and makes positioning of the contacts on the surfaces of substrate 1 easier.

In order to take advantage of a Back Surface Field effect, the back surface of substrate 1 is covered by an electrically conductive passivation film 2 which is more conductive than the substrate. Passivation film 2 enables recombination between the electrons and holes at the level of the back surface of substrate 1 to be reduced, which improves the efficiency of the photovoltaic cell.

This passivation film 2 can be formed by a doped layer of substrate 1 or a more strongly doped layer of substrate 1, i.e. made from semiconductor material. For example purposes, if substrate 1 is of p-type, the front surface is n-doped so as to form the photovoltaic junction and the back surface is p+ doped, i.e. of p-type with a larger concentration of active dopants than in the part of substrate 1 directly in contact with passivation film 2.

Doping is obtained by means of dopant impurities, for example boron or aluminium for a p-type substrate. The passivation film comprises at least one doped semiconductor film, preferably made from the same material as that which forms the substrate.

The photovoltaic cell also comprises a collection layer 3 made from electrically conductive material. This collection layer 3 presents a lower resistivity than that of substrate 1 and of film 2. In preferential manner, the resistivity of the materials reduces progressively when moving away from the photovoltaic junction towards the conductive contacts of the back surface.

At the level of the back surface of the cell, collection layer 3 made from conductive material makes extraction of the current easier to perform. Electrically conductive collection layer 3 is advantageously made from metallic material, i.e. a pure metal or a metal alloy. Collection layer 3 is separated from substrate 1 by passivation film 2.

In order to reduce the stresses exerted by collection layer 3 on substrate 1, the latter is suspended or at least partially suspended, i.e. collection layer 3 is secured to the substrate by means of one or more connection patterns 4 and it comprises at least one suspended area. There is therefore at least one area without stress transfer between passivation film 2 and collection layer 3. This particular area is for example a void area or an area filled by a fluid.

The photovoltaic cell comprises a deformable cavity delineated on one side by passivation film 2 and on the opposite side by collection layer 3. Depending on the embodiments, the cavity can be laterally delineated by a closed peripheral connection pattern and/or it can include a connection pattern 4. Depending on the organization of the void areas and of connection patterns 4, the different void areas can be delineated by the side walls of the connection patterns. A void area is therefore surrounded by a connection pattern. On the contrary, in another embodiment, the different void areas able to be seen in the cross-sectional view communicate with one another, and this represents one or more distinct connection patterns separated by a void area.

Connection pattern 4 then maintains an area of collection layer 3 in suspension with respect to passivation film 2. The photovoltaic cell is therefore a cell which comprises cavities of air or another fluid, preferably a gas, within its structure. If several patterns 4 are formed, at least one of these has to be electrically conductive to ensure electric connection between substrate 1 and collection layer 3

Connection pattern 4 can be formed by any electrically conductive material. In preferential manner, the connection pattern is formed from passivation film 2, from collection layer 3, from another material or from a combination of these cases. This enables the complexity of the fabrication method and physical-chemical compatibility problems to be limited.

Collection layer 3 is in electric contact with substrate 1 by means of connection patterns 4 made from electrically conductive material. Connection patterns 4 have uncovered sidewalls. These side walls extend from passivation film 2 up to collection layer 3.

This particular architecture thereby enables the mechanical influence of collection layer 3 to be limited by limiting its contact surface with substrate 1 by means of connection patterns 4. A sufficient contact surface does however have to be kept to ensure flow of the current and to prevent delamination of collection layer 3. The extent of the contact surface and its distribution on the back surface depend on the mechanical and electrical properties of the materials constituting passivation film 2, collection layer 3 and connection pattern 4.

Connection pattern 4 is an element that is salient from collection layer 3 and from passivation film 2 so as to prevent direct contact between these two layers.

Connection pattern 4 can originate from formation of a salient area of passivation film 2. It can also originate from formation of a salient area of collection layer 3. It can further be formed from another electrically conductive material arranged between passivation film 2 and collection layer 3. It can also be envisaged to combine several of these previous embodiments.

Connection pattern 4 can thus be formed by a doped semiconductor material, by a metallic material or by a material of metallic nature such as an alloy between a metallic material and a semiconductor material. The distance separating collection layer 3 from passivation film 2 can be comprised between a few nanometres and a few hundred micrometres. In preferential manner, the distance is comprised between one and fifty micrometres.

If several connection patterns 4 are integrated, the different patterns can present dimensional differences between one another as far as the length, width and height of the pattern are concerned. The different patterns can also present chemical composition differences. For example purposes, certain patterns are made from semiconductor material whereas others are made from an alloy of a semiconductor material with a metallic material.

As illustrated in FIG. 1, connection patterns 4 are formed by a different material from that forming collection layer 3 and from that forming passivation film 2.

As illustrated in FIG. 2, connection patterns 4 are formed from the same material as that forming passivation film 2.

If several connection patterns 4′ are integrated, it is conceivable that certain will essentially serve the purpose of mechanical securing whereas the function of others will mainly be that of electric current transit.

For example purposes, collection layer 3 is made from aluminium and/or silver, and passivation film 2 is made from p+ doped silicon.

In preferential manner, if collection layer 3 comprises areas having different resistivities, for example porous and non-porous areas, areas having variable filling ratios or areas formed by different materials, connection patterns 4 are associated with the areas having the lowest resistivity.

Connection pattern 4 has a common surface with passivation film 2 and an opposite common surface with collection layer 3. These two opposite walls are located on each side of pattern 4 and are preferably equivalent or substantially equivalent in their extent.

Collection layer 3 can be formed by a single metallic material, by different metallic materials arranged next to one another or by a metallic material alloy. Thus, as illustrated in FIG. 1, collection layer 3 can be formed by a layer made from a first metallic material, for example aluminium. Electrically conductive patterns 5, made from a second metallic material, for example silver (FIG. 1), are formed on the collection layer. It is also possible to have a layer 3 formed by a first metallic material with inclusions made from a second metallic material (FIG. 2), for example patterns 5.

Obtaining a suspended collection layer 3 firmly secured to the rest of the cell by one or more connection patterns 4 is then particularly advantageous for mastering the stresses in the cell.

Obtaining a photovoltaic cell is achieved by a method that is simple to implement and that uses few specific steps compared with a conventional method.

The photovoltaic junction is obtained by any conventional method. The steps relative to formation of the front surface of the cell are not modified and are therefore not represented. In preferential manner, the different technological steps relative to the front surface are performed before those of the back surface. It is however possible to perform certain steps of the front surface before or during those of the back surface and vice-versa.

As illustrated in FIG. 3, a passivation film 2 is formed by any suitable technique on the back surface of substrate 1. In preferential manner, passivation film 2 is formed by doping of substrate 1. This doping can be performed by ion implantation or by heat treatment in a dopant atmosphere. It is also possible to deposit a doped semiconductor material.

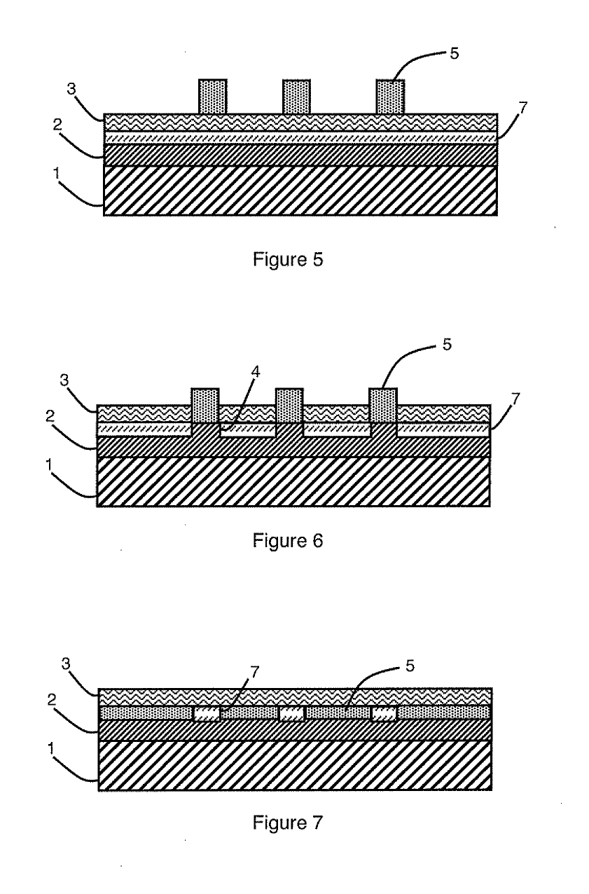

As illustrated in FIG. 4, formation of passivation film 2 is then followed by deposition of a collection material 6 which will form collection layer 3. Collection material 6 can be formed by any suitable technique.

In a preferred embodiment, the order of the steps is reversed. Passivation film 2 is obtained by deposition followed by annealing of a dopant layer, for example made from aluminium. This annealing of the dopant layer simultaneously forms the aluminium collection layer, a layer of aluminium and silicon alloy and a passivation layer 3 made from silicon doped by aluminium atoms. This succession of layers results from diffusion of the silicon and aluminium atoms when annealing is performed.

Collection material 6 is typically a metallic material or an alloy of metallic materials deposited on the passivation film. This collection material 6 is then subjected to heat treatment in order to make it partially react with passivation film 2 to form a connection film 7. A part of the thickness of collection material 6 thus forms connection film 7 whereas the rest of the material forms collection layer 3.

Connection film 7 is then partially etched so as to form at least one connection pattern 4 and a suspended area in collection layer 3. This results in connection pattern 4 being formed from an alloy between a metallic material and the semiconductor material (connection film 7).

In this embodiment, partial etching of connection film 7 enables connection patterns 4 to be formed which participate in current transit. Etching of connection film 7 is performed by any suitable technique, for example by wet or gaseous method, by patterning collection layer 3 or by using structural particularities of the latter.

If collection layer 3 presents non-homogeneities in permeability to the degradation agent, connection patterns 4 can easily be obtained by using differences of behaviour.

If collection layer 3 is relatively homogeneous and/or to precisely locate positioning of connection patterns 4, collection layer 3 is partially covered by one or more protection patterns 5.

In preferential manner, collection layer 3 is formed by a material permeable to an degradation agent of layer 7 and to the degradation sub-product. This permeability enables an degradation agent to be made to pass through collection layer 3. The sacrificial material is thus eliminated by the degradation agent which forms void areas and suspended areas of collection layer 3.

Localisation of degradation of the sacrificial material by the degradation agent is controlled by means of protection patterns. The protection patterns are formed at the surface of the collection layer and make certain portions impermeable to the degradation agent. The positioning and extent of these protection patterns then enables connection patterns 4 of sacrificial material to be defined. Collection layer 3 is preferably formed by a material having a filling ratio of less than 70% and it is partially filled by protection pattern 5 in the area to be protected.

If protection patterns 5 are electrically conductive, they can also act as conducting contacts for the photovoltaic cell.

If permeability to the degradation agent and to the etching sub-product is not an intrinsic characteristic of the collection layer, it is possible to make only a part of the layer permeable. Under these conditions, protection patterns 5 can be avoided.

In preferential manner, permeability of the collection layer is obtained by using a porous layer or a layer comprising porous areas. However, it can also be envisaged to form holes, circulation channels, within the collection layer to etch the sacrificial material.

The use of a degradation agent passing through a permeable collection layer 3 and an impermeable conductive protection pattern 5 enables self-alignment of the conductive contacts with connection patterns 4 to be achieved. The path taken by the current to be output from the cell is thus minimal and the fabrication method is simple.

For example, if collection material 6 is made from aluminium or contains areas made from aluminium, the sacrificial material is made from a silicon and aluminium alloy and the degradation agent is a hydrochloric acid-based solution or a solution of hydrochloric acid only.

The protection patterns are formed in materials which do not react or which react very little to the etching agent so as to prevent elimination of the sacrificial film immediately underneath the protection pattern. The dimensions and shape of the connection patterns depend on the etching mode used and on the dimensions of the protection patterns.

The protection material is for example a silicon oxide formed by any suitable technique, for example by screen printing. The thickness of the protection material is advantageously greater than or equal to 10 μm.

In case of formation of a silicon oxide by screen printing, annealing is advantageously performed in order to stabilize the latter. For example purposes, annealing of about 5 minutes between 100° C. and 200° C. is sufficient for stabilization of silicon oxide.

Connection pattern 4 and protection pattern 5 are thus arranged facing one another on each side of collection layer 3 and present an equivalent contact surface with collection layer 3.

Protection pattern 5 can be made from a conductive material or from an electrically insulating material, for example from silver, silicon oxide or silicon nitride.

In a second embodiment, protection pattern or patterns 5 are formed before collection material 6. Patterns 5 are therefore in direct contact with passivation film 2. The collection material can cover the protection patterns or leave the latter apparent. There then exist areas in which collection material 6 is in direct contact with passivation film 2 and areas in which this contact is impossible due to protection pattern 2.

If heat treatment is performed, collection material 6 reacts with passivation film 2 except in the locations covered by protection patterns 5. In this way, connection film 7 separates collection layer 3 from passivation film 2 except in the areas covered by patterns 5, as illustrated in FIGS. 6 and 7.

In a first example case, partial or total etching of connection film 7 enables the suspended structure to be achieved. Collection layer 3 is maintained above passivation film 2 by the protection patterns which act as connection patterns and possibly by non-etched areas of connection film 7 (FIG. 3).

Depending on whether collection material 6 covers the connection patterns or not (FIGS. 6 and 7), mechanical securing is performed either by the top surface of the connection pattern or by the side surfaces.

In a second example case, connection film 7 acts as connection pattern and protection pattern 5 covered by the collection layer is at least partially eliminated (FIG. 7). Collection layer 3 is then suspended by means of the areas of connection film 7 and possibly by means of protection patterns (FIG. 1).

It is further possible to combine these two approaches in order to functionalize the back surface. For example, if the protection patterns are formed from an insulating material, they only serve the purpose of mechanical securing.

This embodiment is particularly interesting as there is no need to control the etching conditions, as the degradation agent in fact eliminates a single material, the sacrificial material.

In preferential manner, the additional connection patterns are formed perpendicularly to the conductive protection patterns 5 in a plane parallel to the surface of substrate 1. In even more preferential manner, the additional areas connect two areas associated with adjacent contacts. This particular arrangement enables the risks of delamination to be reduced and variations at the level of the field lines present on the back surface to be prevented.

Thus, to obtain a photovoltaic cell having a suspended portion, it is necessary to provide a substrate 1 provided with a photovoltaic junction and covered on one main surface by passivation film 2, an area made from sacrificial material and the collection layer. The area made from sacrificial material can be the connection film or a part of the latter or a protection pattern. The sacrificial area then has to be etched to form a suspended area in collection layer 3 and a connection pattern 4 between passivation film 2 and collection layer 3.

1-10. (canceled)

11. A photovoltaic cell comprising:
a substrate comprising a photovoltaic junction,
an electrically conductive collection layer,
an electrically conductive passivation film separating the collection layer from a back face of the substrate, and
an electrically conductive connection pattern configured to maintain an area of the electrically conductive collection layer in suspension with respect to the electrically conductive passivation film.

12. The cell according to claim 11, wherein the electrically conductive passivation film is made from semiconductor material.

13. The cell according to claim 11, wherein the connection pattern is made from an alloy of semiconductor material and of metallic material.

14. The cell according to claim 11, wherein the electrically conductive collection layer is made from semiconductor material.

15. The cell according to claim 11, wherein the electrically conductive collection layer is partially covered by a protection pattern and wherein the connection pattern and the protection pattern are arranged facing one another on each side of the electrically conductive collection layer.

16. The cell according to claim 15, wherein the electrically conductive collection layer is formed by a porous material and is partially filled by the protection pattern.

17. The cell according to claim 11, wherein:
the substrate is a silicon substrate,
the electrically conductive passivation film is made from p-doped silicon,
the electrically conductive collection layer is made of aluminium,
the electrically conductive connection pattern is made from a silicon-aluminium alloy,
the cell further comprising a protection pattern made from silicon oxide covering the electrically conductive connection pattern and separated form the electrically conductive connection pattern by the electrically conductive collection layer.

18. A method for producing a photovoltaic cell comprising the following steps:
providing a substrate provided with a photovoltaic junction and covered on a back surface by an electrically conductive passivation film, a sacrificial material area and an electrically conductive collection layer, and
etching the sacrificial material area so as to form a suspended area in the electrically conductive collection layer and a connection pattern between the electrically conductive passivation film and the electrically conductive collection layer.

19. The method according to claim 18, wherein the sacrificial material area is made from aluminium and silicon alloy and is etched by a hydrochloric acid solution through a permeable area of the electrically conductive collection layer.

20. The method according to claim 19, wherein the electrically conductive collection layer and protection pattern are deposited by screen printing.
